(19) United States
(12) Patent Application Publication
(10) Pub. No.: US 2026/0261880 A1
(43) Pub. Date: Sep. 3, 2026

(54) SYSTEMS AND METHODS FOR DIGITAL INFRASTRUCTURE SERVICES

(71) Applicant: Huawei Technologies Co., Ltd., Shenzhen (CN)

(72) Inventors: Remziye Irem Bor Yaliniz, Ottawa (CA); Hang Zhang, Ottawa (CA); Nimal Gamini Senarath, Ottawa (CA)

(21) Appl. No.: 19/661,181

(22) Filed: Apr. 28, 2026

Related U.S. Application Data
(63) Continuation of application No. PCT/CN2024/091238, filed on May 6, 2024.
(60) Provisional application No. 63/595,426, filed on Nov. 2, 2023.

(51) Int. Cl. H04W 24/06; G06F 30/20; H04W 24/04

(52) U.S. Cl. CPC H04W 24/06; G06F 30/20; H04W 24/04

(57) ABSTRACT

The present disclosure discloses a method and system for providing digital infrastructure services in a digital world. An example method includes instantiating, by a digital representation module, digital representations in the digital world, the digital representations corresponding to digital replicas of real-world objects, instantiating, by a digital infrastructure module, a digital infrastructure in the digital world, the digital infrastructure corresponding to a real-world infrastructure, the real-world infrastructure comprising the real-world objects, the digital infrastructure comprising the digital representations corresponding to the digital replicas of the real-world objects, transmitting real-world data, by the real-world objects, through a communication plane, to at least one of the digital representation module and the digital infrastructure module, and providing, by at least one service module, the digital infrastructure services to a user using the communication plane.

### CROSS-REFERENCE TO RELATED APPLICATIONS

This application is a continuation of International Patent Application No. PCT/CN2024/091238, filed on May 06, 2024, which claims priority to and the benefits of U.S. Provisional Patent Application Serial No. 63/595,426, filed on November 02, 2023. The disclosures of the aforementioned applications are hereby incorporated by reference in their entireties.

### TECHNICAL FIELD

The technical field relates to digital worlds, and more specifically to systems and methods for providing digital infrastructure services in a digital world.

### BACKGROUND

Many new trends will influence the design of future wireless network technologies, such as 6G, such as new capabilities, matured approaches, new apps and services, more collaborative operations, and stricter requirements. New capabilities can include broadly deployed infrastructures designed for cloud computing. Matured approaches can include large-scale machine learning (ML) models, data privacy, blockchains, and other technologies that have made significant progress and that significantly impact the entire society and human life. New apps and services can include artificial intelligence (AI) services, data generation, e.g., sensing services, digital world services, and any other types of services that are broadly applied in industry or business and used by individual ss. New expectation and stricter requirements on future networks also drive rethinking and development of new generation of wireless networks, such as requirements for privacy and trust, simplified standardization, and rapid deployment.

All of the above drives 6G network architecture research work. Accordingly, there is a continued need to provide solutions that enable above the requirements.

### SUMMARY

The present disclosure proposes a network architecture for 6G. This architecture is a service-based architecture offering anything-as-a-service (XaaS) and is cloud-native. Such as architecture must support new 6G services which could be developed and/or deployed by third parties, must embrace a more open ecosystem to open the door to technically capable third parties, and must enable better trust management.

In accordance with an aspect, a system for providing digital infrastructure services in a digital world is provided. A digital infrastructure is associated with a real-world infrastructure, which can for instance include buildings, roads, cities, robot fleets, factories, railways, cars and/or wireless network equipment. One or more service modules are provided.

As an example, the service modules can include an operation optimization service module to offer Operation Optimization-as-a-service (OaaS) in order to allow a user to optimize the operations of an infrastructure. As another example, the service modules can include an asset management service module to offer Asset Management-as-a-service (AaaS or AMaas) in order to assist the user to manage the infrastructure, and in particular the assets of the infrastructure. As a further example, the service modules can include a virtual reality service module to offer Virtual Reality-as-a-service (VRaaS) in order to provide a virtual reality library for providing real-world data related to an infrastructure to a virtual reality application.

These services are offered by the means of a digital infrastructure in the digital world. This digital infrastructure may be instantiated by a digital infrastructure module and corresponds to a real-world infrastructure which includes real-world objects. The real-world objects can in turn each correspond to a digital representation in the digital world instantiated by a digital representation module, each digital representation being a digital replica of the real-world object. Thus, a digital infrastructure can include digital representations. A communication plane may also be provided in order to enable the digital infrastructure services.

In accordance with another aspect, there is provided a method for providing digital infrastructure services in a digital world, the method comprising: instantiating, by a digital representation module, digital representations (D-Rep) in the digital world, the digital representations corresponding to digital replicas of real-world objects; instantiating, by a digital infrastructure module, a digital infrastructure (D-Inf) in the digital world, the digital infrastructure corresponding to a real-world infrastructure, the real-world infrastructure comprising the real-world objects, the digital infrastructure comprising the digital representations corresponding to the real-world objects; transmitting real-world data, by the real-world objects, through a communication plane, to at least one of the digital representation module and the digital infrastructure module; and providing, by at least one service module, the digital infrastructure services to a user using (or via) the communication plane.

In accordance with a further aspect, there is provided a system for providing digital infrastructure services in a digital world, the system comprising: a digital representation module configured for instantiating digital representations (D-Rep) in the digital world, the digital representations corresponding to digital replicas of real-world objects; a digital infrastructure module configured for instantiating a digital infrastructure (D-Inf) in the digital world, the digital infrastructure corresponding to a real-world infrastructure, the real-world infrastructure comprising the real-world objects, the digital infrastructure comprising the digital representations corresponding to the real-world objects; a communication plane configured for the real-world objects to transmit real-world data to at least one of the digital representation module and the digital infrastructure module; and at least one service module configured for providing the digital infrastructure services to a user using (or via) the communication plane.

In accordance with yet another aspect, there is provided a computer readable medium comprising computer instructions that when executed by at least one processor provide digital infrastructure services in a digital world, the instructions configured to: instantiate, by a digital representation module, digital representations (D-Rep) in the digital world, the digital representations corresponding to digital replicas of real-world objects; instantiate, by a digital infrastructure module, a digital infrastructure (D-Inf) in the digital world, the digital infrastructure corresponding to a real-world infrastructure, the real-world infrastructure comprising the real-world objects, the digital infrastructure comprising the digital representations corresponding to the real-world objects; transmit real-world data, by the real-world objects, through a communication plane, to at least one of the digital representation module and the digital infrastructure module; and provide, by at least one service module, the digital infrastructure services to a user using (or via) the communication plane.

In accordance with yet a further aspect, there is provided a system for providing digital infrastructure services in a digital world, the system comprising: a memory storing instructions; and one or more processors configured to execute the instructions and cause the system to: instantiate, by a digital representation module, digital representations (D-Rep) in the digital world, the digital representations corresponding to digital replicas of real-world objects, instantiate, by a digital infrastructure module, a digital infrastructure (D-Inf) in the digital world, the digital infrastructure corresponding to a real-world infrastructure, the real-world infrastructure comprising the real-world objects, the digital infrastructure comprising the digital representations corresponding to the real-world objects, transmit real-world data, by the real-world objects, through a communication plane, to at least one of the digital representation module and the digital infrastructure module, and provide, by at least one service module, the digital infrastructure services to a user using (or vai) the communication plane.

### BRIEF DESCRIPTION OF THE DRAWINGS

For a better understanding of the embodiments described herein and to show more clearly how they may be carried into effect, reference will now be made, by way of example only, to the accompanying drawings which show at least one exemplary embodiment.

FIG. 1 is a simplified schematic view of a communication system, in accordance with an embodiment.

FIG. 2 is a schematic view of an embodiment of a communication device operating in the communication system of FIG. 1, in accordance with an embodiment.

FIG. 3 is a schematic view of a 6G system conceptual structure, in accordance with an embodiment.

FIG. 4 is a schematic view of a digital world platform of wireless networks, including a digital infrastructure platform, in accordance with an embodiment.

FIG. 5 is a schematic view of exemplary digital infrastructure instances with associated data interfaces, in accordance with an embodiment.

### DETAILED DESCRIPTION OF ILLUSTRATIVE EMBODIMENTS

It will be appreciated that, for simplicity and clarity of illustration, where considered appropriate, reference numerals may be repeated among the figures to indicate corresponding or analogous elements or steps. In addition, numerous specific details are set forth in order to provide a thorough understanding of the exemplary embodiments described herein. However, it will be understood by those of ordinary skill in the art that the embodiments described herein may be practised without these specific details. In other instances, well-known methods, procedures and components have not been described in detail so as not to obscure the embodiments described herein. Furthermore, this description is not to be considered as limiting the scope of the embodiments described herein in any way but rather as merely describing the implementation of the various embodiments described herein.

In the present disclosure, a digital representative (“D-Rep”) refers to a virtual or digital replica, also named “digital twin”, of a real-world entity and/or object in a digital world (DW). The D-Rep digitally mimics its associated real-world entity for practical purposes such as simulation and testing, for example. For instance, the real-world entity can transmit entity data to the D-Rep such that the D-Rep can maintain a similar state as its real-world counterpart. For example, the data can include sensor data, logical state, and input/output values. Since the D-Rep is a digital equivalent to its associated real-world entity, a behaviour of the real-world entity, current or expected, can be accurately simulated by performing simulations with the D-Rep. Therefore, D-Reps can be useful in a number of application areas. Further, a D-Rep may be generated to represent real-world entities having different abstraction levels. In the area of communications, abstraction levels can be split into a communication region, a cellphone, a base station (BS), an antenna, or a chip in the radio-frequency (RF) chain, for example. A given D-Rep abstraction level can be determined based on the application, prediction/simulation goals, available data, available analytical or computational resources, for example. In some embodiments, D-Reps are instantiated and managed by a digital representation module, e.g., distributed or non-distributed software and/or hardware operating on a network.

In the present disclosure, a digital infrastructure (“D-Inf”), refers to a digital replica and/or representative in the digital world of a real-world infrastructure that includes a collection of real-world objects having a relative degree of cooperation and/or integration. For example, the real-world entities can include, without being limited to, buildings, roads, robots, factories, railways, cars, wireless network equipment and resources each having associated D-Reps, and the D-Inf can be a collection of all those D-Reps. For example, the D-Inf can be a digital representative of a city encompassing all those real-world entities. As further examples, the D-Inf can correspond to: buildings and roads in a smart city; to wireless network elements, such as channel, base stations (BS), relays, drones, satellites, NFs and servers; to factories, production lines, and other types of robotic equipment; and/or to intelligent transportation systems including city railways, etc. It should be noted that, in some embodiments, the city may be a D-rep, such as a digital infrastructure of a geographical region including the city, while in other embodiments, it may be a D-Inf. Therefore, in the following description, a D-Inf can contain the digital representatives (D-Reps) of the real-world objects or entities associated with a given infrastructure, with related integration and application functions. The D-Inf can be referred to as an infrastructure, a system, an apparatus, or the like. In some embodiments, the D-Inf is instantiated and managed by a digital infrastructure module, e.g., distributed or non-distributed software and/or hardware operating on a network.

In the present disclosure, a virtual user (“D-User”) is a D-Inf subplatform corresponding to a digital representative of a user instantiated and maintained inside the network. Since one or more D-Users are stored and maintained inside the network, a D-User can closely interact with the network and/or other digital entities maintained in the network, in order to provide the “real” user with more control over services obtained from the network, i.e., the D-User allows for improved user empowerment. The network services can be provided as added services and can be referred to as User Controlled and Managed (UCM) services.

It can be appreciated that other similar digital subplatforms of D-Inf are possible. As an example, in some embodiments, a digital city (“D-City”) is provided as the subplatform for smart city applications. As another example, in some embodiments, a digital network (“D-Net”) is provided. Generally speaking, any number of unspecified subplatforms “D-X” can be provided.

In the present disclosure, methods and systems for providing services related to a D-Ing are described. These methods and services can depend on methods and/or systems for digitally replicating a real-world infrastructure and maintaining the digital replica and associated digital representatives, such as described for instance in United States Provisional Application No. 63/586,574, having a filing date of September 29, 2023, the entire disclosure of which is incorporated herein by reference. Preferably, the methods and/or systems will be particularly adapted to provide a digital infrastructure (D-Inf) platform including functionalities for supporting data collection, exchange and analysis for the D-Inf.

The methods and systems described herein advantageously allow for providing services related to D-Reps of a D-Inf integrated within a wireless network, providing scalability while helping in reducing data exchange latency of using a distributed architecture. The method and system allow for simulating and performing scenarios, such as prediction scenarios, using the data from D-Rep(s) of real-life entities. A D-Inf can be implemented on elements of a wireless network such as base stations (BSs), core network elements, edge network elements, user equipment (UE), sensor networks, private factory networks, or a cloud of the network, for example. Through the implementation of the D-Inf, various infrastructure services can be offered, such as the Operation Optimization-as-a-service (OaaS), Asset Management-as-a-service (AaaS), and Virtual Reality-as-a-service (VRaaS) services already mentioned and described in more detail below.

### Example Architectures

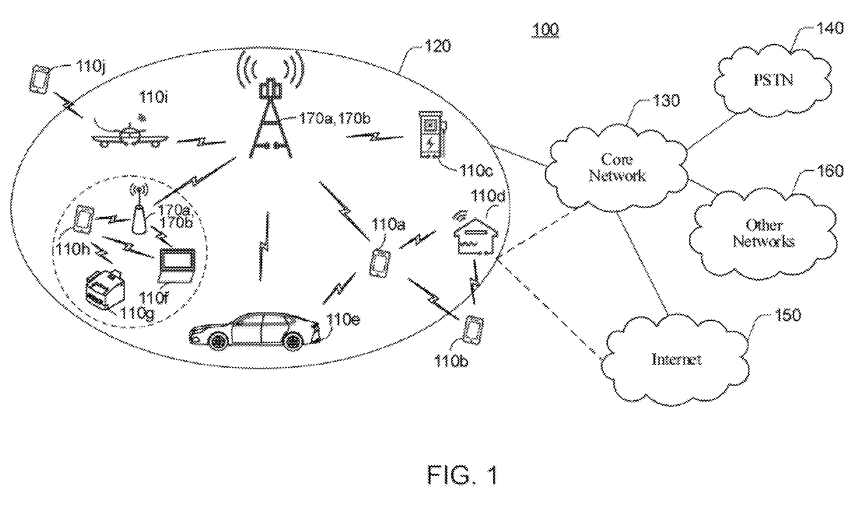

FIGS. 1 to 5 provide exemplary embodiments of network and device architectures suitable for offering these infrastructure services.

With reference to FIG. 1, as an illustrative example without limitation, a simplified schematic illustration of a communication system is provided. The communication system 100 comprises a radio access network 120 (RAN). The radio access network 120 may be a next generation, e.g., sixth generation (6G) or later, radio access network, or a legacy, e.g., 5G, 4G, 3G or 2G, radio access network. One or more communication electronic devices 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 can comprise a public switched telephone network (PSTN) 140, the internet 150, and other networks 160.

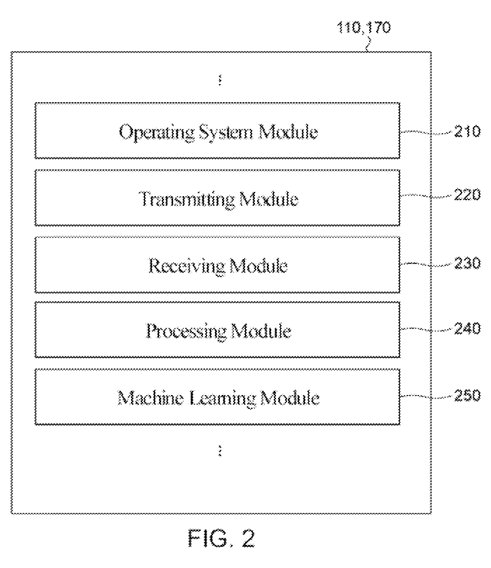

With reference to FIG. 2, units or modules in a communication electronic device 110 or node 170 are shown according to an exemplary embodiment. One or more steps of the method and/or one or more functions of the system embodiments provided herein may be performed by corresponding units or modules. For example, a signal may be transmitted by a transmitting unit or by a transmitting module 220. A signal may be received by a receiving unit or by a receiving module 230. A signal may be processed by a processing unit or a processing module 240. Other steps may be performed by an artificial intelligence (AI) or machine learning (ML) module 250. The respective units or modules may be implemented using hardware, one or more components or devices that execute software, or a combination thereof. For instance, one or more of the units or modules may be a circuit such as an integrated circuit. Examples of an integrated circuit include a programmed FPGA, a GPU, or an ASIC. For instance, one or more of the units or modules may be logical such as a logical function performed by a circuit, by a portion of an integrated circuit, or by software instructions executed by a processor. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation, the whole under the control of an operating system module 210.

One or more modules described herein may be implemented in computer program(s) executed on processing device(s), each comprising at least one processor, a data storage system (including volatile and/or non-volatile memory and/or storage elements), and optionally at least one input and/or output device. “Processing devices” encompass computers, servers and/or specialized electronic devices which receive, process and/or transmit data. As an example, “processing devices” can include processing means, such as microcontrollers, microprocessors, and/or CPUs, or be implemented on FPGAs. For example, and without limitation, a processing device may be a programmable logic unit, a mainframe computer, a server, a personal computer, a cloud-based program or system, a laptop, a personal data assistant, a cellular telephone, a smartphone, a wearable device, a tablet, a video game console or a portable video game device.

Each program is preferably implemented in a high-level programming and/or scripting language, for instance an imperative e.g., procedural or object-oriented, or a declarative e.g., functional or logic, language, to communicate with a computer system. However, a program can be implemented in assembly or machine language if desired. In any case, the language may be a compiled or an interpreted language. Each such computer program is preferably stored on a storage media or a device readable by a general or special purpose programmable computer for configuring and operating the computer when the storage media or device is read by the computer to perform the procedures described herein. In some embodiments, the system may be embedded within an operating system running on the programmable computer.

Furthermore, the system, processes and methods of the described embodiments are capable of being distributed in a computer program product comprising a computer readable medium that bears computer-usable instructions for one or more processors. The computer-usable instructions may also be in various forms including compiled and non-compiled code.

The processor(s) are used in combination with storage medium, also referred to as “memory” or “storage means”. Storage medium can store instructions, algorithms, rules and/or trading data to be processed. Storage medium encompasses volatile or non-volatile/persistent memory, such as registers, cache, RAM, flash memory, ROM, diskettes, compact disks, tapes, chips, as examples only. The type of memory is, of course, chosen according to the desired use, whether it should retain instructions, or temporarily store, retain or update data. Steps of the proposed method are implemented as software instructions and algorithms, stored in computer memory and executed by processors.

It is understood that the neural networks can be implemented using computer hardware elements, computer software elements or a combination thereof. Accordingly, the neural network modules described herein can be referred to as being computer-implemented. Various computationally intensive tasks of the neural network can be carried out on one or more processors (central processing units and/or graphical processing units) of one or more programmable computers.

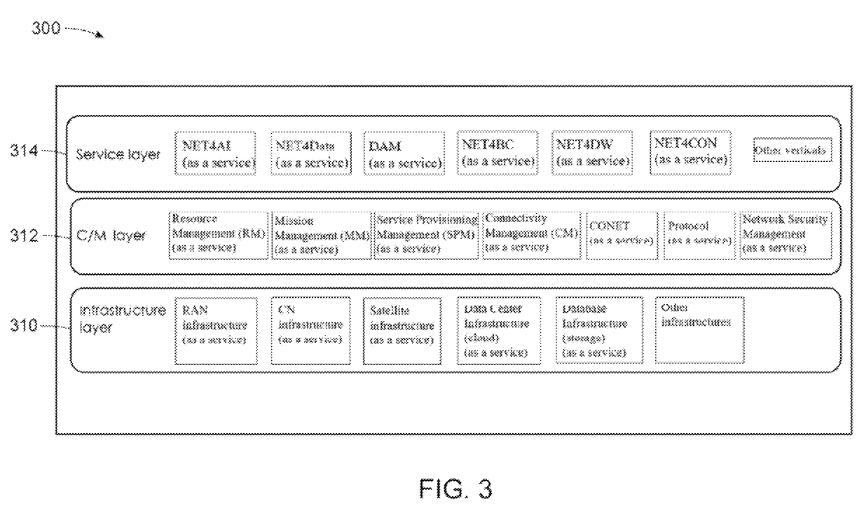

With reference to FIG. 3, a possible embodiment of a 6G system conceptual structure is shown. In some embodiments, the network system 300 leverages service-based architecture and anything-as-a-service (XaaS) concept. XaaS services in the 6G system are categorized into three layers 310, 312, 314.

In possible embodiments, Infrastructure Layer 310 includes infrastructures supporting 6G services. Among them are wireless networks such as RAN or core network (CN) infrastructures, Cloud/data centre infrastructures, satellite networks, storage/database infrastructures, and sensing networks, etc. These infrastructures can be provided by a single provider or by multiple providers.

Each of the infrastructures can have its control and management functions, denoted as Control and Management (C/M) functions, for infrastructure management. Each of these infrastructures can be one type of Infrastructure as a Service.

In possible embodiments, C/M layer 312 includes control and management services of the 6G system, providing a first communication plane. They are developed and deployed by using slicing techniques and utilizing resource provided by infrastructure layer. 6G services in C/M layer 312 may include:

A Resource Management module comprising Resource Management (RM) as a Service function, which can provide a capability of lifecycle management of a variety of slices and over-the-air resource assignment to wireless devices.

A 6G mission module defined as a service provided to customers (or users) by the 6G system. A mission can be a set of services which is provided by a single 6G XaaS service or a type of service that needs contributions from multiple XaaS services.

A Mission Management module comprising Mission Management (MM) as a Service function, which may provide a capability to program provisioning of XaaS services at Service Layer to provide mission services.

A CONET module comprising Confederation Network (CONET) as a Service functions, which may provide a capability to enable multiple partners to jointly provide 6G services. This capability is provided by confederation formation, mutual authentication, mutual authorization among partners and negotiation of agreement on recording and retracing of selected actions performed by partners, in order to assure a trustworthy environment of 6G system operations.

A Service Provisioning Management module functions, which comprises Service Provisioning Management (SPM) as a Service, to provide a capability of control and management of 6G service access by customers and provisioning of requested services. The capability is provided by unified mutual authentication, authorization and policy, key management, QoS assurance and charging between any pair of XaaS service provider and customer. The customers include end customers not only in the physical world, but also digital representatives in the digital world.

A Connectivity Management module, which comprises Connectivity Management (CM) as a Service functions, to leverage 5G connectivity management functions, but with extension to include digital world.

A Protocol as a Service module, which comprises Protocol as a Service functions to provide a capability to design service customized protocol stacks for identified interfaces. The protocol stacks can be predefined for on-demand selection, or can be on-demand designed.

A Network Security as a Service module, which comprises Network Security as a Service functions to provide a capability for owners of infrastructures to detect potential security risks of their infrastructures.

A XaaS module, comprising XaaS services in the C/M Layer support control and management 312 of the 6G system itself and also provide support to verticals if requested. One example is that RM service can serve RAN for over-the-air resource management and can also provide service to a vertical for the vertical’s over-the-air resource allocation to its end customers. The XaaS in C/M layer can be deployed by using slicing technique.

Service Layer 314 may include 6G services which provide services to customers. In the 6G System structure 300, the following modules may be included:

An AI service module, denoted as NET4AI as a Service. Artificial Intelligence service functions provide AI capability to support a variety of AI applications.

A DAM module comprising Service of data collection, data sanitization, data analysis and data delivery functions, denoted as DAM as a Service, this service provides a capability of lifecycle management of statistic data, including acquisition, de-privatization, analysis and delivery of data which are information statistic data from any types of sensors, devices, network functions etc.

A NET4Data module, comprising Service of storage and sharing of data, denoted as NET4Data as a Service. This service module provides a capability to trustworthy storage and share data under the control of owners of data and following recognized authorities’ regulations on control of identified data.

A NET4DW module, comprising Service to provide digital world, denoted as NET4DW as a Service. The Digital World module (or system) provide a capability to construct, control and manage digital world. Digital world is defined as digital realization of physical world.

A block chain module, comprising 6G block chain service is denoted as NET4BC as a Service. 6G connectivity service is denoted as NET4Con as a Service. This service provides a capability to support 6G block chain services.

A NET4CON module, comprising Enhanced connectivity service, e.g., network for connectivity (NET4CON) as a service. This service provides a capability to support exchange of messages and data among new 6G services.

All XaaS services at this layer may be developed and deployed by using resources provided in the infrastructure and utilizing Network Function Virtualization and Slicing techniques. The capability of each of the 6G services is provided by its control and management (C/M) functions and service-specific data process functions.

In addition to supporting 6G XaaS services at Service Layer 314, the 6G System 300 leverages 5G System for provisioning of vertical services. The difference between 6G XaaS services and other verticals are that a vertical is a pure customer who needs other XaaS services to enable its operation, while each of XaaS services provide their capabilities to 6G customers.

Any pair of XaaS services of the 6G system may also be mutual customer and provider of each other. Some examples are that an infrastructure owner providing its resource to XaaS services in the Service Layer 314 and C/M Layer 312; RM services may need the capabilities provided by NET4AI, DAM and NET4DW for its resource management for vertical slicing; CONET service and NET4Data service may need the capability provided by NET4BC for their operation.

The structure and associated modules/platform of the proposed 6G system may provide the following functionalities and advantages:

Define Basic XaaS Services by decoupling comprehensive types of services into basic XaaS services. A basic XaaS service provides unique capability to enable a specific type of service, such as NET4AI service, NET4DW service, DAM service, NET4Data service, blockchain service, mission management service, etc.

Allow joint operation of the 6G system by multiple partners.

Define Data Plane of the 6G System which includes processing functions of data plane of XaaS services, providing a second communication plane. Programing the interconnection of these functions, by mission management service, enables to support a variety of customized customer services.

Simplify 6G system architecture by categorizing basic control services and management services and combining them as basic XaaS services in Control and Management (C/M) Layer.

Define C/M Plane of the 6G System which includes C/M functions in XaaS services and may include 5G CP (e.g., AMF) depending on implementation options.

Define Basic Architecture Structure (BAS) which is a unified basic structure with minimized number of interfaces and is independent of types of infrastructures.

Simplify standardization, development and deployment of the 6G system using the BAS concept, while supporting a variety of infrastructure deployment scenarios.

Adapt to a variety of deployment scenarios by applying the BAS or a subset of it to infrastructures based on capability, capacity and requirement of the infrastructure networks.

Leverage service-based interface (SBI) concept and apply SBI interaction in both 6G C/M plane and 6G data plane.

Simplify SBI interfaces by introducing trustworthy GWs in Data Plane and C/M Plane of the 6G System.

Improve trustworthiness from perspectives of operation of the 6G system by introducing CONET capability, NET4BC capability and anonymous service provisioning provided by the trustworthy GWs in the C/M plane and data plane of the 6G system.

Improve trustworthiness from perspective of end customer privacy protection by unified mutual authentication, IDM, data sanitization, etc. provided by SPM service, DAM service and 6G Block Chain service.

Simplify roaming management of wireless devices, in the physical world and digital world, by unified authentication including all participated partners and customers.

Support multiple development paths from 5G System to 6G System by defining multiple architecture options without incurring much efforts due to the introduction of the BAS concept.

Support backward compatibility by utilizing benefits of service-based architecture and its add-on feature. 5G users can use the 6G system to access 5G services.

Support future extension by adding new XaaS services with minimized impact on standardization and deployment, due to the introduced anonymous service provisioning concept implemented in trustworthy GWs in 6G C/M plane and in 6G.

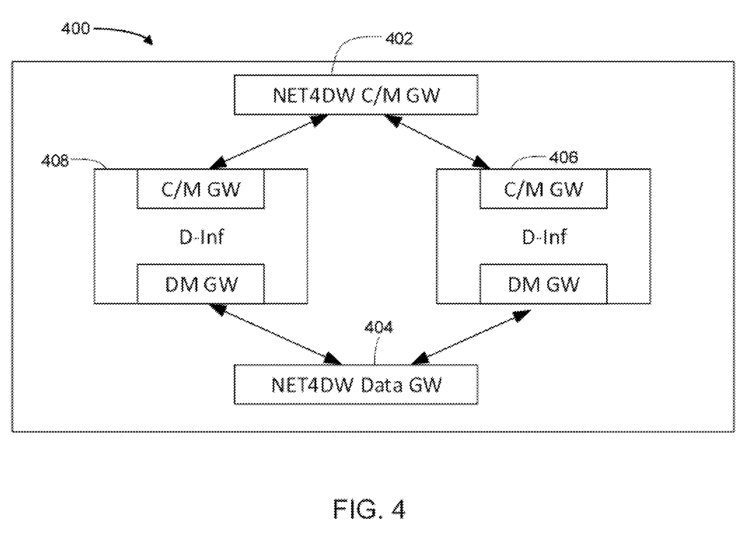

With reference to FIG. 4, an overview of an exemplary view of a NET4DW platform architecture is shown in accordance with an embodiment. Common elements, e.g., databases and functions, are not shown for brevity. The gateways within the D-Infs are optional.

One example platform is the Digital World platform of wireless networks (NET4DW) that can provide a variety of services to enable D-Reps. The module of NET4DW that is responsible for infrastructure D-Reps and sub-platforms may be termed as D-Inf. D-Infs 406, 408 can be instantiated in an exemplary environment 400, such as a Digital World platform of wireless networks (NET4DW). The D-Infs 406, 408 can be accessed from the environment 400 through connecting an environment control and management gateway 402 with a control and management gateway of the D-Inf, and similarly through connecting a environment data gateway 404 with a data gateway of the D-Inf. Such connections enable interactions between the D-Infs 406, 408 and other entities of the environment 400, such as a D-User. External entities, such as other service platforms including Artificial Intelligence platform for wireless networks (NET4AI) or Data management platform for wireless networks (NET4DATA), or third-party entities, can use the GWs to access NET4DW platform. The NET4DW platform can include other modules and platforms as well but they are not shown in the above figure for brevity. External entities, such as other service platforms, e.g., NET4AI, NET4DATA, or third-party entities, e.g., third-party D-Inf subplatform providers can use the gateways to access NET4DW platform. Other options, e.g., direct access to D-Inf entities are further described herein.

The NET4DW D-Inf module may provide the functionalities of replicating the real world by using D-Reps and using D-Reps to run simulations that allow accurate predictions and understanding of the real system. D-Reps can be at different abstraction levels, or granularity levels, e.g., a D-Rep may correspond to a communication region, a cell, a BS, an antenna, or one of the chips in the RF chain. The suitable D-Rep granularity level can be determined based on the application, prediction/simulation goals, available data, available analytical and computational resources and so on.

D-Inf platform C/M and Data Plane functions can include control and management and data functionality, respectively. The necessary C/M and Data Plane functions may depend on the specific application/service and its requirements. For example, if the NET4DW GWs provides sufficient levels of security and anonymity, the D-Inf platform can provide a number of functions in C/M and Data planes, including for instance a data collection function, providing for efficient and customizable data collection for D-Reps, a connection function, providing for secure connections that can satisfy challenging quality-of-service requirement, e.g., low-latency, on a variety of interfaces, a hosting function, providing for secure hosting of D-Reps and lifecycle management, and/or an analysis function, providing for the maintenance of a rich and powerful simulation environment for the optimal effectiveness of D-Reps.

It can be appreciated that several alternative D-Inf services exist in the literature, such as Digital Twins of ports and factories empowered with the support of cloud services. The services are solutions independent of the D-Inf, and there is no platform like D-Inf that can support or provide such services via communication networks. That causes inefficiencies in providing infrastructure services by causing duplications of data collection, analysis and so on. Accordingly, scaling, standardization, accuracy, and efficiency of these services become bottlenecks.

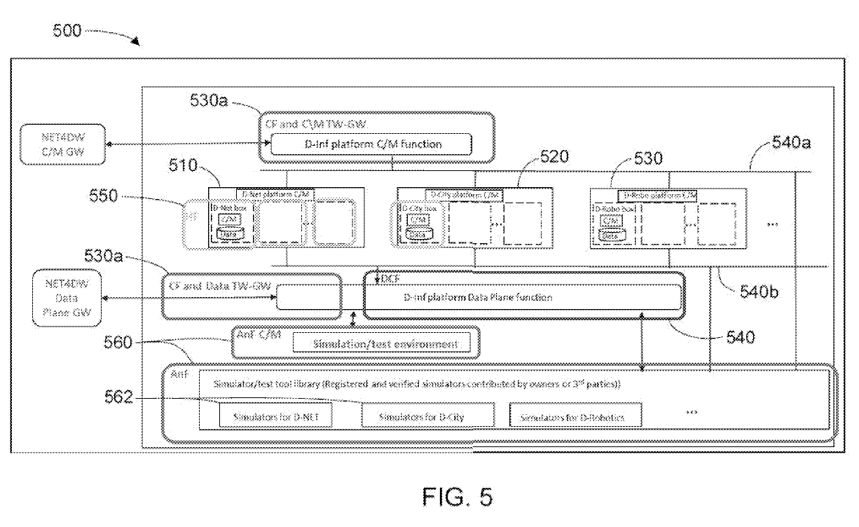

With reference to FIG. 5, a more detailed view of a NET4DW platform and D-Inf platform architecture is shown in accordance with an exemplary embodiment. An environment 500 can include a plurality of D-Inf subplatforms, for instance a Digital Network (D-Net) subplatform 510, a Digital City (D-City) subplatform 520, and a Digital Robot (D-Robo) subplatform 530. The subplatforms 510, 520, 530 are all specialized instances of D-Infs with some specialized functions implemented for each subplatform. The subplatforms are connected to the data collection (DC) function 540 (DCF), the connection function 530a, 530b, the hosting function 550, and the analysis function 560. All subplatforms can access the simulation and test environment by the D-Inf Data Plane function. D-Inf C/M and Data Plane two-way gateway service can be provided by the connection function 530a, 530b. Part or all of the services for the subplatforms 510, 520, 530 can be implemented in the subplatforms directly, or, regardless of how specific they are, as C/M and Data Plane functions and services common to all the D-Inf sub-platforms. The latter implementation can allow multiple D-X boxes, such as D-Inf subplatforms or modules, to access similar functionalities easily and can help reduce duplication. In some embodiments, for example, the two-way gateway functionality can be implemented as a common C/M and Data Plane function for all subplatforms, the DC function may be used to allow data exchange between subplatforms, the hosting function may be used to maintain D-Reps in a D-X box, and the analysis function may maintain the simulation environment 562 resources in the C/M plane and manage the contents of the library in the Data plane.

D-Inf services can make the Digital World useful and profitable. D-Inf can contain the digital representatives of the real-world object and related integration and application functions. In some embodiments, the D-Inf can is the sole provider of D-Rep and subplatform services. In some embodiments, the D-Inf can additionally or alternatively support third-party platforms and service providers. In some embodiments, for a given service, some aspects of the service can be provided by the D-Inf and other aspects can be provided by third-party service providers. In some embodiments, the D-Inf provides at least the fundamental functions, such as connection, collection, hosting, and/or analysis, necessary to obtain digital infrastructures.

In some embodiments, the proposed services include OaaS, AaaS and/or VRaaS described below. In some embodiments, all these services use the connection between specialized D-X boxes (D-Inf subplatforms), which enables efficient data collection, analysis, scaling and customization. D-Inf can include subplatforms further specialized for certain groups of applications. For example, operation optimization service of networks is provided and/or consumed by a D-Net module/subplatform. It can be appreciated that embodiments described herein are directed to products in wireless networks, but are also applicable to other D-Rep and subplatform services as well. In some embodiments, the services are offered and managed at least one service module, e.g., distributed or non-distributed software and/or hardware operating on a network, including for instance an operation optimization service module, an asset management service module and/or a virtual reality service module.

In some embodiments, the services are provided in combination for certain types of applications, services and/or requests. For example, D-Net box/platform can provide a combination of OaaS, where the network is optimized, and AaaS, where the network is maintained. These services can have unique functions/functionalities or may use the common functions of D-Inf platform for their purposes.

The services can be implemented on the BSs, core network elements, edge network elements, user equipment, sensor networks, private factory networks, and in the cloud. When embodiments are used, they may be detected by the messages and input-output relationships. Some services can be fundamentally provided by the network, while some other services can be provided by a third party and supported by the network. For example, in some cases, the hosting network can be the digital world application provider’s network. In some other cases, the D-Inf can support, including solely supporting, the third-party digital world applications. In the first case, the network can maintain the D-Reps, perform simulations and analysis, collect data, etc. In the latter case, where the network supports third-party applications, the network can be responsible only for data collection, or even act as a pipeline between the data source and the digital world application provider. The connectivity service can include connectivity for all means of actuation. For example, the actuation may be stopping a production line, prompting an asset manager for a maintenance alert or changing the scheduling parameters of a BS. Furthermore, services may include mechanisms for decision-making.

As described above, a D-Inf platform can contain a number of D-Reps of various infrastructure, including wireless networks, buildings and intelligent transportation systems. These high-fidelity D-Reps models allow accurate simulations, hence, accurate prediction and optimal operations. In some embodiment, therefore, an Infrastructure Operation Optimization Service is provided. The service can provide a solution for extensive optimization of infrastructure’s operation. While the infrastructure can be of many types and optimization methods can depend on the specific application, D-Inf can address these requirements as a global digitization platform.

In some embodiments, an operation optimization service module is provided to implement OaaS, allowing a customer, or a user, associated with the D-Inf to improve, or optimize, the infrastructure operations. As examples OaaS can include prediction services, such as predictive blockage detection, allowing for reliable communications in the case of network infrastructures, estimating or predicting the occupancy of a building at any given time, estimating or predicting the energy expenditure of a building for any given period of time, and estimating or predicting the yield, production and/or capacity of specific pieces of equipment and/or of production lines. It can be appreciated that, when making predictions related to a building, depending on the level of granularity, the real-world-building can be represented by the D-Inf or can be represented by at least one D-Rep associated with the D-Inf. When making predictions related to a piece of equipment and/or to a production, it is expected that the piece of equipment is a real-world object represented by at least one D-Rep, and/or that the production line includes at least one real-world object represented by at least one D-Rep.

In some embodiments, OaaS includes determining the requirements for performing certain types of analysis, prediction and/or services, in general or in relation with a configurable desired level of accuracy. These requirements can depend on the box and the specific purpose of the analysis. The requirements can include data collection requirements, analysis software and platform/hardware requirements, storage requirements (e.g., for historical data), etc.

In some embodiments, the requirements include D-Rep granularity requirements. For instance, OaaS can determine which D-Reps are needed and the minimum level of granularity to obtain the required level of accuracy. As an example, a BS may be represented as a box or as a collection of many other D-Reps, such as antennas, processing units, cables, etc. As another example, a building may be represented as a whole or as an association of different floors, rooms, HVAC systems, etc. Different levels of granularity can be suitable for different types of analysis. The digital representation module can be configured to instantiate the suitable D-Reps given the desired or computed granularity requirements.

In some embodiments, the requirements include age-of-information (AoI) management requirements. Making accurate predictions to improve or optimize operations can rely on timely data. OaaS can evaluate and apply various parameters as part of operation optimization, including for instance time-sensitive networking, adaptation and synchronization of clocks and specific synchronization needs, in order to adjust the data collection quality as necessary for the desired level of accuracy.

In some embodiments, based on the determined requirements, OaaS includes collecting the necessary real-world data from real-world objects associated with the D-Reps of the D-Inf, for instance using one of the communication panes defined above. In some embodiments, data collection tunnels can be established to encapsulate and transmit real-world data, for instance between sensors of real-world devices or objects and corresponding D-Reps, between sensors of real-world objects and the corresponding D-Inf, and/or between D-Reps and the D-Inf. In some embodiments, a module implementing the D-Inf can be said to obtain real-world data from real-world objects via a module implementing the D-Reps. In some embodiments, real-world data can be fetched from external sources, such as third-party platforms and/or other platforms. In some embodiments, real-world data can be fetched from internal sources such as internal databases.

In some embodiments, OaaS includes storing fetched real-world data, analysis results, and/or other data. In some embodiments, OaaS can compute a storage space necessary to collect a predetermined quantity of historical data and analysis results. In some embodiments, OaaS can compute an amount of historical data and analysis results possible to collect in a predetermined storage space.

In some embodiments, OaaS provides operation optimization in view of complying with one or more predetermined standard, e.g., a technical standard such as an ISO™ or an ANSI™ standard such as the ISO 55000 standard. In some embodiments, OaaS can evaluate the performance of operations of the infrastructure. In some embodiments, OaaS can determine a level of compliance of an infrastructure with the predetermined standard(s), for instance based on the performance. In some embodiments, OaaS can provide an indicator of compliance. This indicator of compliance can for instance include a percentage of compliance of the infrastructure with the predetermined standard(s).

Both real-world and digital world assets require lifecycle and maintenance management. The D-Inf is ubiquitous and allows for fast, scalable, and customizable deployment. Therefore, an Infrastructure Asset Management Service can provide a solution for proactive lifecycle and maintenance management of physical and digital assets. AaaS can provide both short-term and real-time health management of infrastructure assets, and analysis and prediction on long-term strategic view on usage and health of the infrastructure. AaaS facilitates asset management by providing a scalable, multidisciplinary and integrated platform. When multiple real-world entities are a part of the same D-Rep, they can be maintained by AaaS in real time.

In some embodiments, an asset management service module is provided to implement AaaS. Several exemplary use cases are applicable for AaaS. One example is water treatment facilities, road infrastructure and aging buildings. In this case, the customers, or users, can be municipalities, government organizations or private organizations responsible for the maintenance of these facilities. Another example is the management of a fleet of robots, for instance elderly care robots. In this scenario, a customer, or user, owning multiple robots can monitor the health of the robots and the service quality they offer. For instance, AaaS makes it possible to make short-term analysis and predictions, in order to develop long-term strategies to manage the fleet. In some embodiments, the D-Rep-based process can learn the characteristics of robots and the tasks. As an example, AaaS for a robot fleet can include assigning a unique identifier to each robot, e.g., a “robot ID”, and to each task, e.g., a “task ID”, in order to enable the collaborative learning and classification of tasks by mapping the robot behaviour to complex tasks. A robot fleet can thereby leverage digital world services to make its operations safer and more efficient, and the operator of the robot fleet can gain access to ubiquitous connectivity, data management, processing and analysis capabilities. In a further example, a logistics company can use AaaS and leverage technologies such as a Space-Air-Ground Integrated Network to manage remote entities such as freighters, ships, and/or aircrafts.

In some embodiments, AaaS includes using real-world data to monitor and/or assess the condition, or “health”, of real-world objects which correspond to assets of the infrastructure being managed, for instance using sensors installed in, on or near each object. In some embodiments, AaaS includes using the health assessment of objects to make short and/or long-term predictions and/or planning for the infrastructure. As an example, current and/or historical real-world data related to objects of the infrastructure can be used to perform long-term usage and/or health predictions of assets, and/or to provide a maintenance planning service. The maintenance planning service can analyze the real-world data in order to predict maintenance requirements of assets. In some embodiments, the maintenance planning service is configured to generate and/or optimize a maintenance schedule.

In some embodiments, AaaS includes a subscription management service to improve the coordination, e.g., of the staff of the customer, or user, with respect to asset management. The subscription management service can include broadcasting the results of health assessments and analysis, and/or maintenance planning to subscribed entities, or subscribers, e.g., customer staff members. In some embodiments, each subscriber is associated with a level, e.g., an access control management level, and the data and/or information provided to the subscriber is a function of the subscriber’s level. In some embodiment, the data and/or information is classified, processed and prepared based on each subscriber's level. In some embodiments, information containers are automatically updated and/or formatted for usability and ease of consumption by the customer and/or the subscribers. In some embodiments, the subscription management service includes triggering alarms based on data, information and/or an analysis thereof. As an example, alarms can be triggered based on a health data, for instance including a health assessment of an asset. In some embodiments, data labelling methods are applied to generate codes regarding alarms, maintenance and/or results.

In some embodiments, AaaS includes collecting the necessary real-world data from real-world objects associated with the D-Reps of the D-Inf that are being monitored, for instance using similar communication means and/or data sources as defined above with respect to OaaS. In some embodiments, both local and global data is collected and stored. In some embodiments, the data collection is augmented by or integrated with a geographical information system (GIS). In some embodiments, the data collection is augmented by or integrated with a building information model and/or a building information modelling (BIM) system.

In some embodiments, AaaS data collection relies partially or wholly on integrated sensing and communication capabilities of wireless networks. As an example, passive network elements and/or access points, and preferably access points with multiple antennas can be used for scanning to sense data, e.g., health-related data, of surrounding real-world objects associated with D-Reps, such as buildings. In some embodiments, at least one base station is configured to scan the nearby buildings and roads, advantageously during off-peak hours. The result of the scans can be pre-processed at the access point, and/or raw scans can be sent to the digital world and/or to the asset management service module and/or provider. In some embodiments, the asset management service provider is the network itself, as described further above. In some embodiments, specific network equipment, for instance some or all of the access points, are equipped with sensing elements such as reconfigurable intelligent surfaces. In some embodiments, the base station operates in combination with one or more reconfigurable intelligent surfaces. In some embodiments, the collected information, including the results of the scans, is stored, processed, and/or used, e.g., by the digital representation module, to obtain and/or update D-Reps of the infrastructure. In some embodiments, the results of the scans are compared to previously collected information to assess the accuracy and/or effectiveness of the scans. The previously collected information can include for instance BIM model(s), GIS model(s), LiDAR scans, map information, and/or material information including data related to building materials such as concrete, plastic, etc., used in the construction of objects. In some embodiments, scanning parameters are adjusted based on the assessed accuracy and/or effectiveness of the scans. Adjusting the scanning parameters can for instance include updating beamforming. In some embodiments, the health of an infrastructure and/or of the assets associated with the infrastructure is assessed based on the scans, without the use of additional equipment. The approaches described herein create a highly connected environment that manages data and computing aspects efficiently, which is advantageous for both the operator and the customers or users, especially when large-scale projects are considered.

In some embodiments, AaaS includes a certification requirement analysis service that assists in bringing or maintaining an infrastructure in compliance with one or more standards, e.g., technical standards such as the ISO 55000 standard. AaaS can advantageously be used to specify D-Rep and digital world criteria necessary to comply with predetermined standard(s), using up-to-date blueprints of certification requirements. In some embodiments, if a customer, or user, requires an infrastructure to comply with a certain standard, the requirements for it are derived based on the specific AaaS needs of the customer, or user. In some embodiments, the certification requirement analysis service provides for interpreting and/or explaining for specific standards. For instance, a Hosting Function may request an Analysis Function to explain the artificial intelligence algorithms necessary to comply with standardization, and/or to improve and/or fine-tune the algorithms. As an example, if a first subplatform uses a first method to provide a service, and a second subplatform uses a second method to provide the same service, and if the first method provides better performance, e.g., for instance by providing more accurate results, and/or by providing results using less computational resources and/or less data, AaaS can suggest that the second subplatform uses the first method. In some embodiments, in order to provide this service, the Analysis Function can make a request to the Data Collection Function in order to collect performance information of methods used to provide similar services.

VRaaS can provide a solution to enable extended, augmented and virtual reality services by customizable deployments. The D-Rep services of the D-Inf, along with other services, e.g., of the NET4DW, can help satisfy challenging requirements of virtual reality services, e.g., by reducing the latency by providing accurate predictions. VRaaS can use not only user equipment input from the virtual reality customers, or users, but can also leverage sensing data from the network and other surrounding elements.

In some embodiments, a virtual reality service module is provided to provide an extensive virtual reality (VR) library. As an example, the D-Inf can be used to provide a library and/or database, e.g., of rooms, of city parts such as streets, malls, etc., to support VR services. In some embodiments, relevant information can be cached such that it is available from a location closer to a VR server or user. In some embodiments, the network environment and/or capability information and/or analysis can be shared with the digital representatives of the user (D-User) to allow the user to modify its own traffic. In some embodiments, the D-Inf can be the provider of the VR service as well.

In some embodiments, VRaaS is used to provide a VR application. As an example, a VR asset management service can be provided. In some embodiments, the VR asset management service generates detailed reports and adjust the information level based on the consumers of the report, as explained in more detail above with respect to AaaS. In some embodiments, realistic VR representations of assets can be created to generate a tridimensional visual representation. The VR asset management service can facilitate repair, maintenance, reporting, etc. As an example, when a damage and/or repair report needs to be prepared, the VR-based information/video/application can be broadcast to and/or shared with the stakeholders. The detail of the shared information/report can be adjusted based on the level of the receiver of the reports, such that for instance some subscribers receive restricted access, some receive complete access, some receive reports with manager level abstractions, and some receive reports with additional technical details. These reports may also easily adapt to standardized templates.

In some embodiments, VRaaS support by D-Inf includes interactions between several NET4DW platforms, such as D-User, D-City and D-Net, allowing for cross-box environment sensing service. As an example, the sensing data, analysis and/or predictions can be used not only to describe the surrounding environment, but also to provide information about network capabilities to VR customers or users, e.g., the end user, the VR service provider, or another VR service supporter. VRaaS can thereby provide for cross-D-Inf-box optimization.

In the present disclosure, the terms “a”, “an” and “one” are defined to mean “at least one”, that is, these terms do not exclude a plural number of items, unless stated otherwise.

In the present disclosure, terms such as “substantially”, “generally” and “about”, which modify a value, condition or characteristic of a feature of an exemplary embodiment, should be understood to mean that the value, condition or characteristic is defined within tolerances that are acceptable for the proper operation of this exemplary embodiment for its intended application.

In the present disclosure, unless stated otherwise, the terms “connected” and “coupled”, and derivatives and variants thereof, refer herein to any structural or functional connection or coupling, either direct or indirect, between two or more elements. For example, the connection or coupling between the elements can be acoustical, mechanical, optical, electrical, thermal, logical, or any combinations thereof.

In the present disclosure, expressions such as “match”, “matching” and “matched”, including variants and derivatives thereof, are intended to refer herein to a condition in which two or more elements are either the same or within some predetermined tolerance of each other. That is, these terms are meant to encompass not only “exactly” or “identically” matching the two elements but also “substantially”, “approximately” or “subjectively” matching the two or more elements, as well as providing a higher or best match among a plurality of matching possibilities.

In the present disclosure, the expression “based on” is intended to mean “based at least partly on”, that is, this expression can mean “based solely on” or “based partially on”, and so should not be interpreted in a limited manner. More particularly, the expression “based on” could also be understood as meaning “depending on”, “representative of”, “indicative of”, “associated with” or similar expressions.

In the present disclosure, “at least one” means one or more, and “a plurality of” means two or more. “and/or” describes an association relationship of associated objects, and indicates that there may be three relationships. For example, A and/or B may indicate cases includes “only A”, “both A and B”, and “only B”, where A and B may be singular or plural. The character “/” generally indicates that the associated objects are in an OR relationship. “At least one of the following items” or a similar expression thereof refers to any combination of these items, including any combination of a single item or a plurality of items. For example, “at least one of a, b, or c” may represent a, b, c, “a and b”, “a and c”, “b and c”, or “a, b and c”, where a, b, and c may be a single or multiple form.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

What is claimed is:

1. A method for providing digital infrastructure services in a digital world, the method comprising:
instantiating, by a digital representation module, digital representations in the digital world, the digital representations corresponding to digital replicas of real-world objects;
instantiating, by a digital infrastructure module, a digital infrastructure in the digital world, the digital infrastructure corresponding to a real-world infrastructure, the real-world infrastructure comprising the real-world objects, the digital infrastructure comprising the digital representations corresponding to the digital replicas of the real-world objects;
transmitting real-world data, by the real-world objects, through a communication plane, to at least one of the digital representation module or the digital infrastructure module; and
providing, by at least one service module, the digital infrastructure services to a user using the communication plane.

2. The method of claim 1, wherein the at least one service module comprises at least one of:
an operation optimization service module configured to allow the user associated with the digital infrastructure to modify operations of the real-world infrastructure;
an asset management service module configured to assist the user to manage assets of the real-world infrastructure; or
a virtual reality service module configured to provide at least a virtual reality library for providing the real-world data to a virtual reality application.

3. The method of claim 1, wherein the real-world data is transmitted to the digital infrastructure module via the digital representation module.

4. The method of claim 2, further comprising scanning, by an access point, at least one of the real-world objects of the real-world infrastructure corresponding to the digital infrastructure to obtain scan results.

5. The method of claim 4, wherein the access point comprises a reconfigurable intelligent surface, wherein the scanning is performed by the reconfigurable intelligent surface.

6. The method of claim 2, further comprising determining and applying synchronization needs required to obtain a configurable accuracy by at least one of the at least one service module.

7. The method of claim 2, further comprising instantiating the digital representations by the digital representation module with different abstraction levels, wherein the different abstraction levels are determined based on at least one of application, prediction goal, simulation goal, available data, available analytical resources, or available computational resources.

8. The method of claim 2, further comprising performing at least one prediction by the operation optimization service module, the at least one prediction comprising at least one of:
a prediction of a blockage of a network;
a prediction of an occupancy of a building, wherein the building corresponds to the real-world infrastructure or to one of the real-world objects of the real-world infrastructure corresponding to the digital infrastructure;
a prediction of an energy expenditure of the building;
a prediction of a yield of an equipment, wherein the equipment corresponds to one of the real-world objects of the real-world infrastructure corresponding to the digital infrastructure; or
a prediction of a capacity of a production line, wherein the production line comprises at least one of the real-world objects of the real-world infrastructure corresponding to the digital infrastructure.

9. The method of claim 2, further comprising determining, by the operation optimization service module, requirements for one of the at least one service module to provide the digital infrastructure services with a configurable accuracy, wherein the requirements comprise at least one of:
an age of information management requirement indicative of a data collection quality;
a data collection requirement;
an analysis software or hardware requirement; or
a storage requirement based on a determined required quantity of historical data.

10. The method of claim 9, further comprising fetching the real-world data from the real-world objects via the digital representations and the communication plane by at least one of the at least one service module in accordance with the determined requirements.

11. The method of claim 2, further comprising measuring a performance of the real-world infrastructure corresponding to the digital infrastructure by the operation optimization service module.

12. The method of claim 2, further comprising managing health of the real-world infrastructure corresponding to the digital infrastructure in real time by the asset management service module based on the real-world data.

13. The method of claim 12, wherein the user is associated with subscribers, wherein the health management comprises the asset management service module generating at least one of health data or formatted data updates, and broadcasting the at least one of the health data or the formatted data updates to the subscribers.

14. The method of claim 13, further comprising classifying, processing, and preparing the health data by the asset management service module based on each of the subscribers.

15. The method of claim 2, further comprising performing, by the asset management service module, at least one long-term prediction based on historical real-world data, the at least one long-term prediction comprising at least one of:
a long-term usage prediction of the real-world infrastructure corresponding to the digital infrastructure; or
a long-term health prediction of the real-world infrastructure corresponding to the digital infrastructure.

16. The method of claim 10, wherein fetching the real-world data comprises the asset management service module pre-processing the fetched real-world data.

17. The method of claim 2, further comprising predicting maintenance requirements of the real-world infrastructure corresponding to the digital infrastructure by the asset management service module.

18. The method of claim 2, further comprising monitoring, by the virtual reality service module, interactions between the digital infrastructure and at least one other digital box comprising at least one of:
at least one digital user, each corresponding to a representative of a real-world user in the digital world;
at least one digital city, each corresponding to a representative of a real-world city in the digital world; or
at least one digital network, each corresponding to a representative of a real-world network in the digital world.

19. A system for providing digital infrastructure services in a digital world, the system comprising:
a digital representation module configured for instantiating digital representations in the digital world, the digital representations corresponding to digital replicas of real-world objects;
a digital infrastructure module configured for instantiating a digital infrastructure in the digital world, the digital infrastructure corresponding to a real-world infrastructure, the real-world infrastructure comprising the real-world objects, the digital infrastructure comprising the digital representations corresponding to the digital replicas of the real-world objects;
a communication plane configured for the real-world objects to transmit real-world data to at least one of the digital representation module or the digital infrastructure module; and
at least one service module configured for providing the digital infrastructure services to a user using the communication plane.

20. A non-transitory computer readable storage medium comprising computer instructions that, when executed by at least one processor of a system providing digital infrastructure services in a digital world, cause the system to:
instantiate, by a digital representation module of the system, digital representations in the digital world, the digital representations corresponding to digital replicas of real-world objects;
instantiate, by a digital infrastructure module of the system, a digital infrastructure in the digital world, the digital infrastructure corresponding to a real-world infrastructure, the real-world infrastructure comprising the real-world objects, the digital infrastructure comprising the digital representations corresponding to the digital replicas of the real-world objects;
transmit real-world data, by the real-world objects, through a communication plane of the system, to at least one of the digital representation module or the digital infrastructure module; and
provide, by at least one service module of the system, the digital infrastructure services to a user using the communication plane.
